(19) United States
(12) Patent Application Publication
(10) Pub. No.: US 2025/0098079 A1
(43) Pub. Date: Mar. 20, 2025

(54) SUPPORT MEMBER FOR DISPLAY DEVICE, DISPLAY DEVICE COMPRISING THEREOF, AND METHOD FOR MANUFACTURING THEREOF

(71) Applicant: Samsung Display Co., LTD., Yongin-si (KR)

(72) Inventors: MINSOK JANG, Yongin-si (KR); SUNGGUK AN, Yongin-si (KR); HIROTSUGU KISHIMOTO, Yongin-si (KR); JONGBIN PARK, Yongin-si (KR); CHUL HO JEONG, Yongin-si (KR); JUNHUN CHA, Yongin-si (KR)

(21) Appl. No.: 18/749,122

(22) Filed: Jun. 20, 2024

(30) Foreign Application Priority Data
Sep. 20, 2023 (KR) 10-2023-0125947

(51) Int. Cl. H05K 5/02

(52) U.S. Cl. CPC H05K 5/02

(57) ABSTRACT

A support member for a display device includes a first support layer and a second support layer. The first support layer includes a first area, a second area, and a third area between the first area and the second area. The second support layer directly contacts a first surface of the first support layer. The second support layer includes a material different from a material of the first support layer. The second support layer includes a stretchable portion overlapping the third area, and at least one opening is defined in the stretchable portion.

This application claims priority to Korean Patent Application No. 10-2023-0125947, filed on Sep. 20, 2023, all the benefits accruing therefrom under 35 U.S.C. § 119, the content of which in its entirety is herein incorporated by reference.

### BACKGROUND

### 1. Field

Embodiments of the invention relate to a support member for a display device and a display device including the support member. More particularly, embodiments of the invention relate to a support member for a display device that can prevent a display panel from being deformed due to an external force or the like, and a display device including the support member.

### 2. Description of the Related Art

Flat panel display devices are replacing cathode ray tube display devices as display devices due to their lightweight and thin characteristics. As representative examples of such flat panel display devices, there are liquid crystal display devices and organic light emitting diode display devices.

A display device may include a display panel and a support member disposed under the display panel. The support member may prevent the display panel from being deformed due to an external force or the like.

### SUMMARY

In a display device including a display panel and a support member, rigidity increase and thickness reduction of the support member may be desirable.

Embodiments of the invention provide a support member for a display device with a reduced thickness.

Embodiments of the invention also provide a display device with a reduced thickness.

Embodiments of the invention also provide a method of manufacturing a support member for a display device with a reduced thickness.

Additional features of the inventions will be set forth in the description which follows, and in part will be apparent from the description, or may be learned by practice of the inventions.

A support member for a display device according to an embodiment includes a first support layer and a second support layer. In such an embodiment, the first support layer includes a first area, a second area, and a third area between the first area and the second area. In such an embodiment, the second support layer directly contacts a first surface of the first support layer. In such an embodiment, the second support layer includes a material different from a material of the first support layer. In such an embodiment, the second support layer includes a stretchable portion overlapping the third area and at least one opening is defined in the stretchable portion.

In an embodiment, a thickness of the second support layer may be greater than a thickness of the first support layer.

In an embodiment, the first support layer may include a polymer resin. The second support layer may include at least one selected from a metal, an alloy, and a reinforced fiber composite.

In an embodiment, the first support layer may include at least one selected from a metal, an alloy, and a reinforced fiber composite. In such an embodiment, the second support layer may include a polymer resin.

In an embodiment, the third area may extend in a first direction. In such an embodiment, a plurality of openings spaced apart from each other may be defined in the stretchable portion of the second support layer, and each of the plurality of openings may extend the first direction.

In an embodiment, a length of each of the plurality of openings in the first direction may be less than a length of the second support layer in the first direction. In such an embodiment, the plurality of openings may be arranged in the first direction and a second direction crossing the first direction.

In an embodiment, the support member for the display device may further include a coating layer overlapping the third area, extending in the first direction, and disposed between the first support layer and the second support layer.

In an embodiment, a first surface of the coating layer may directly contact the first surface of the first support layer. a second surface of the coating layer opposite to the first surface may be not adhered to the stretchable portion of the second support layer.

In an embodiment, the second support layer may further include a first support portion overlapping the first area and a second support portion overlapping the second area. In such an embodiment, the first support portion and the second support portion may be directly contact the first surface of the first support layer. In such an embodiment, the stretchable portion may be spaced apart from the first surface of the first support layer.

In an embodiment, the second support layer may include a first surface facing the first surface of the first support layer and a second surface opposite to the first surface. A distance between the first surface of the first support layer and the second surface of the second support layer in the first area may be less than a distance between the first surface of the first support layer and the second surface of the second support layer in the third area.

In an embodiment, a length of each of the plurality of openings in the first direction may be equal to a length of the second support layer in the first direction. In such an embodiment, the plurality of openings may be arranged in a second direction crossing the first direction.

In an embodiment, the third area may extend in a first direction. In such an embodiment, an opening extending in the first direction and overlapping the entire third area may be defined in the stretchable portion of the second support layer.

In an embodiment, the support member for the display device may further include a first elastic layer overlapping the third area, extending in the first direction, positioned within the opening of the second support layer, and directly contacting the first surface of the first support layer.

In an embodiment, the first elastic layer may directly contact an inner side surface of the second support layer, where the inner side surface may define the opening.

In an embodiment, a thickness of the first elastic layer may be equal to a thickness of the second support layer.

In an embodiment, the first elastic layer may have a first surface facing the first surface of the first support layer and a second surface opposite to the first surface. The support member for the display device may further include a second elastic layer attached on the second surface of the first elastic layer.

In an embodiment, a thickness of the first elastic layer may be less than a thickness of the second support layer.

In an embodiment, the support member for the display device may further include a third support layer directly contacting a second surface of the first support layer and including a same material as the first support layer. The second surface of the first support layer may be opposite to the first surface of the support layer.

A display device according to an embodiment includes a display panel and a support member. In such an embodiment, the display panel includes a first non-folding area, a second non-folding area, and a folding area between the first non-folding area and the second non-folding area, and a support member disposed under the display panel. In such an embodiment, the support member includes a first support layer and a second support layer. In such an embodiment, the first support layer has a first surface facing the display panel and a second surface opposite to the first surface. In such an embodiment, the second support layer directly contacts the second surface of the first support layer. In such an embodiment, the second support layer includes a material different from a material of the first support layer. In such an embodiment, the second support layer includes a stretchable portion overlapping the folding area, and at least one opening is defined in the stretchable portion.

A method of manufacturing a support member for a display device according to an embodiment includes directly disposing a second support layer including a material different from a material of a first support layer on the first support layer, the first support layer including a first area, a second area, and a third area between the first area and the second area, bonding the first support layer and the second support layer to each other via thermocompression bonding, forming a photoresist layer on the second support layer, where the photoresist layer overlaps the third area and includes a pattern portion in which at least one opening is defined, forming a stretchable portion in the second support layer by selectively etching the second support layer using the photoresist layer as an etching mask, where the stretchable portion overlaps the third area and at least one opening is defined in the stretchable portion, and removing the photoresist layer.

The support member for the display device according to embodiments may include the first support layer and the second support layer directly contacting the first support layer. Accordingly, it is possible to decrease a thickness of the support member for the display device.

### BRIEF DESCRIPTION OF THE DRAWINGS

The above and other features of the invention will become more apparent by describing in further detail embodiments thereof with reference to the accompanying drawings, in which

FIG. 1 is a plan view illustrating a display device according to an embodiment;

FIG. 2 is a cross-sectional view illustrating a folded state of the display device of FIG. 1;

FIG. 3 is a cross-sectional view taken along line I-I′ of FIG. 1;

FIG. 4 is an enlarged cross-sectional view of area ‘A’ of FIG. 3;

FIG. 5 is a rear view illustrating an example of a support member included in the display device of FIG. 3;

FIG. 6 is a rear view illustrating another example of a support member included in the display device of FIG. 3;

FIGS. 7 to 13 are views schematically illustrating a method of manufacturing a support member for a display device according to an embodiment;

FIG. 14 is a cross-sectional view illustrating a display device according to another embodiment;

FIGS. 15 and 16 are cross-sectional views illustrating a display device according to still another embodiment;

FIG. 17 is a cross-sectional view illustrating a display device according to still another embodiment;

FIG. 18 is a cross-sectional view illustrating a display device according to still another embodiment;

FIG. 19 is a cross-sectional view illustrating a display device according to still another embodiment;

FIG. 20 is a plan view illustrating a display device according to still another embodiment; and

FIGS. 21 to 23 are cross-sectional views taken along line II-II′ of FIG. 20.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. The same reference numerals are used for the same components in the drawings, and redundant descriptions of the same components will be omitted or simplified.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

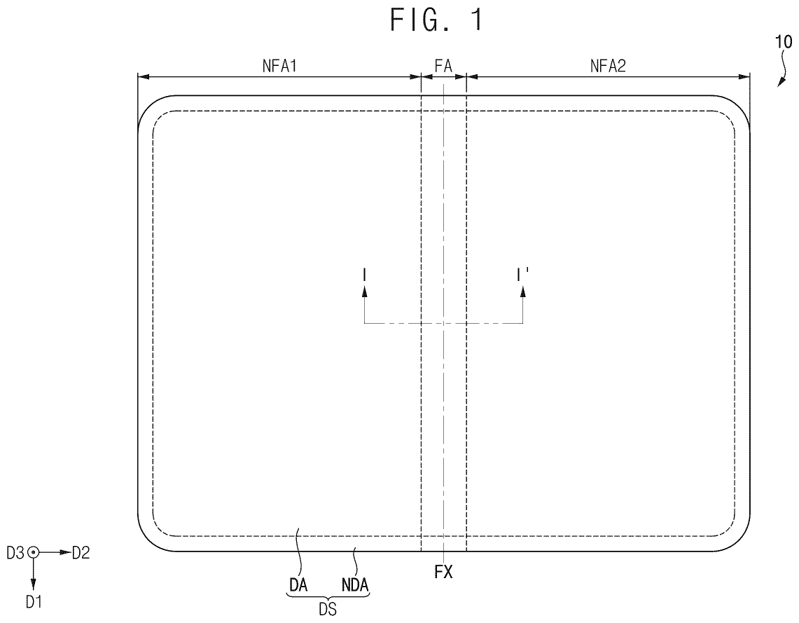

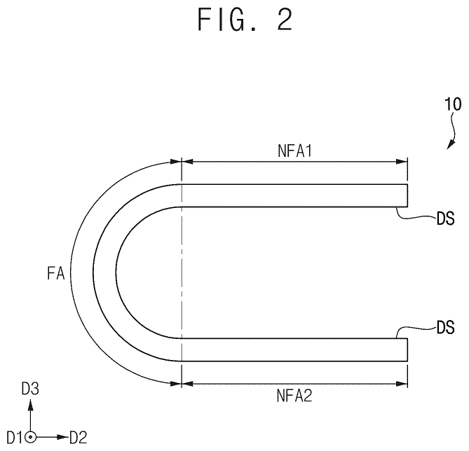

FIG. 1 is a plan view illustrating a display device according to an embodiment. FIG. 2 is a cross-sectional view illustrating a folded state of the display device of FIG. 1.

Referring to FIGS. 1 and 2, an upper surface of a display device 10 may be defined as a display surface DS. The display surface DS may have a plane defined by a first direction D1 and a second direction D2 crossing the first direction D1. For example, the second direction D2 may be perpendicular to the first direction D1. An image generated by the display device 10 may be provided to an user through the display surface DS in a third direction D3 perpendicular to the first direction D1 and the second direction D2. Here, the third direction D3 may be a thickness direction of the display device 10.

The display surface DS may include a display area DA and a non-display area NDA. The display area DA may display the image, and the non-display area NDA may not display the image. The non-display area NDA may be positioned around the display area DA. In an embodiment, for example, the non-display area NDA may surround the display area DA in a plan view.

In an embodiment, the display device 10 may be a flexible display device. The display device 10 may be a foldable display device which can be folded or unfolded. The display device 10 may include a first area NFA1, a second area NFA2, and a third area FA. The second area NFA2 may be spaced apart from the first area NFA1 in the second direction D2. The third area FA may be positioned between the first area NFA1 and the second area NFA2. The third area FA may extend in the first direction D1.

The third area FA may be bent along a folding axis FX parallel to the first direction D1, when the display device 10 is folded. In an embodiment, as illustrated in FIG. 2, the display device 10 may be in-folded that the display surface DS is not exposed to an outside. That is, when the display device 10 is folded, the first area NFA1 and the second area NFA2 of the display surface DS may face each other. In another embodiment, the display device 10 may be out-folded that the display surface DS is exposed to the outside.

The first area NFA1, the second area NFA2, and the third area FA may be referred to as a first non-folding area, a second non-folding area, and a folding area, respectively. Although an embodiment of the display device 10 including two non-folding areas (the first area NFA1 and the second area NFA2) and one folding area (the third area FA) in FIG. 1, but this is an example and embodiments are not limited thereto. In an embodiment, for example, the display device 10 may include three or more non-folding areas and two or more folding areas between the non-folding areas.

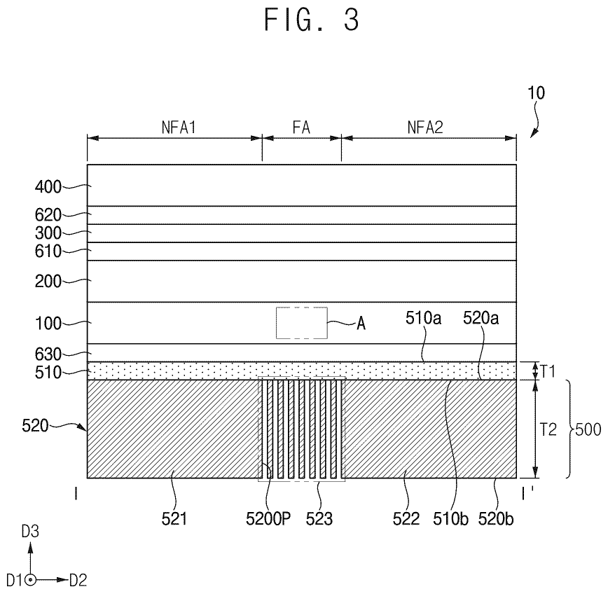

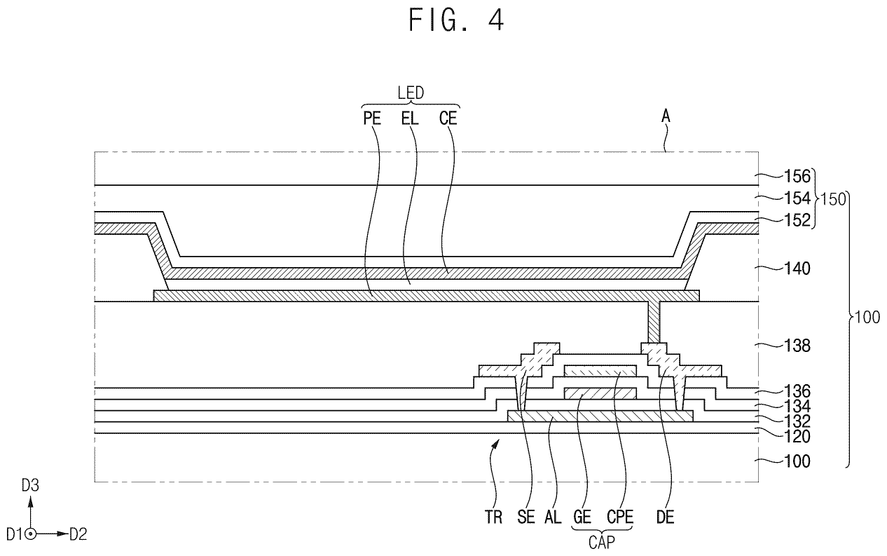

FIG. 3 is a cross-sectional view taken along line I-I′ of FIG. 1. FIG. 4 is an enlarged cross-sectional view of area ‘A’ of FIG. 3.

Referring to FIGS. 1 and 3, in an embodiment, the display device 10 may include a display panel 100, a polarizing member 200, a cover window 300, a window protection layer 400, and a support member 500. As described above, the display device 10 may include the first area NFA1, the second area NFA2, and the third area FA. Each of the display panel 100, the polarizing member 200, the cover window 300, the window protection layer 400, and the support member 500 may include the first area NFA1, the second area NFA2, and the third area FA. The polarizing member 200, the cover window 300, and the window protection layer 400 may be disposed above the display panel 100 (e.g., in the third direction D3 perpendicular to the first direction D1 and the second direction D2). The support member 500 may be disposed under the display panel 100 (e.g., in a direction opposite to the third direction D3).

The display panel 100 may include a plurality of pixels for generating the image. The pixels may be arranged in the display area DA. The light emitted from the pixels may be combined to generate the image. In an embodiment, for example, the pixels may be arranged in a matrix form in the first direction D1 and the second direction D2.

Hereinafter, the pixels of the display panel 100 will be described in detail with reference to FIG. 4. Referring to FIG. 4, the display panel 100 may include a substrate 110, a buffer layer 120, the pixels, insulating layers 132, 134, 136, and 138, a pixel defining layer 140, and an encapsulation layer 150. Each of the pixels may include a transistor TR, a capacitor CAP, and a light emitting element LED.

The substrate 110 may be an insulating substrate including or formed of a transparent material or a non-transparent material. In an embodiment, the substrate 110 may include plastic and may have flexibility. In such an embodiment, the display panel 100 may be a flexible display panel.

The buffer layer 120 may be disposed on the substrate 110. The buffer layer 120 may prevent or reduce impurities such as oxygen or moisture from penetrating into an upper portion of the substrate 110 through the substrate 110. The buffer layer 120 may include an inorganic material. In an embodiment, for example, the buffer layer 120 may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These can be used alone or in a combination thereof. The buffer layer 120 may have a single-layered structure or a multi-layered structure including a plurality of insulating layers.

The transistor TR and the capacitor CAP may be disposed on the buffer layer 120. The transistor TR may include an active layer AL, a gate electrode GE, a source electrode SE, and a drain electrode DE.

The active layer AL may be disposed on the buffer layer 120. The active layer AL may include an oxide semiconductor, a silicon semiconductor, an organic semiconductor, or the like. In an embodiment, for example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer AL may include a source area, a drain area, and a channel area positioned between the source area and the drain area.

A first insulating layer 132 may be disposed on the active layer AL. The first insulating layer 132 may cover the active layer AL on the buffer layer 120. The first insulating layer 132 may include an inorganic insulating material.

The gate electrode GE may be disposed on the first insulating layer 132. The gate electrode GE may overlap the channel area of the active layer AL. The gate electrode GE may include a conductive material such as a metal, an alloy, a conductive metal nitride, a conductive metal oxide, a transparent conductive material, or the like. In an embodiment, for example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These can be used alone or in a combination thereof. The gate electrode GE may have a single-layered structure or a multi-layered structure including a plurality of conductive layers.

A second insulating layer 134 may be disposed on the gate electrode GE. The second insulating layer 134 may cover the gate electrode GE on the first insulating layer 132. The second insulating layer 134 may include an inorganic insulating material.

A capacitor electrode CE may be disposed on the second insulating layer 134. The capacitor electrode CE may overlap the gate electrode GE. The gate electrode GE, the second insulating layer 134, and the capacitor electrode CE may form the capacitor CAP.

A third insulating layer 136 may be disposed on the capacitor electrode CPE. The third insulating layer 136 may cover the capacitor electrode CPE on the second insulating layer 134. The third insulating layer 136 may include an inorganic insulating material.

The source electrode SE and the drain electrode DE may be disposed on the third insulating layer 136. The source electrode SE and the drain electrode DE may be connected to the source area and the drain area of the active layer ACT, respectively. Each of the source electrode SE and the drain electrode DE may include a conductive material.

A fourth insulating layer 138 may be disposed on the source electrode SE and the drain electrode DE. The fourth insulating layer 138 may include an organic insulating material. In an embodiment, for example, the fourth insulating layer 138 may include photoresist, polyacryl-based resin, polyimide-based resin, polyamide-based resin, siloxane-based resin, acryl-based resin, epoxy-based resin, or the like. These can be used alone or in a combination thereof.

A pixel electrode PE may be disposed on the fourth insulating layer 138. The pixel electrode PE may include a conductive material. The pixel electrode PE may be connected to the drain electrode DE through a contact hole defined or formed in the fourth insulating layer 138. Accordingly, the pixel electrode PE may be electrically connected to the transistor TR.

The pixel defining layer 140 may be disposed on the pixel electrode PE. The pixel defining layer 140 may cover a peripheral portion of the pixel electrode PE, and may define a pixel opening exposing a central portion of the pixel electrode PE. The pixel defining layer 140 may include an organic insulating material.

An emission layer EL may be disposed on the pixel electrode PE. The emission layer EL may be disposed in the pixel opening of the pixel defining layer 140. In some embodiments, the emission layer EL may include at least one of an organic light emitting material or quantum dot.

In an embodiment, the organic light emitting material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may serve as a protection layer for preventing the core from being chemically denatured to maintain semiconductor characteristics, and may serve as a charging layer for imparting electrophoretic characteristics to the quantum dot.

A common electrode CE may be disposed on the emission layer EL. The common electrode CE may also be disposed on the pixel defining layer 140. The common electrode CE may include a conductive material. The pixel electrode PE, the emission layer EL, and the common electrode CE may form the light emitting element LED.

The encapsulation layer 150 may be disposed on the common electrode CE. The encapsulation layer 150 may include at least one inorganic encapsulation layer and at least one organic encapsulation layer. In an embodiment, the encapsulation layer 150 may include a first inorganic encapsulation layer 152 disposed on the common electrode CE, an organic encapsulation layer 154 disposed on the first inorganic encapsulation layer 152, and a second inorganic encapsulation layer 156 disposed on the organic encapsulation layer 154. In addition, although not illustrated in the drawing, various functional layers such as a touch sensing layer, a color filter layer, a light collecting layer, or the like may be additionally disposed on the encapsulation layer 150.

Referring back to FIGS. 1 and 3, the polarizing member 200 may be disposed on the display panel 100. The polarizing member 200 may block external light incident on the display panel 100 from the outside. In some embodiments, the polarizing member 200 may be omitted.

The cover window 300 may be disposed on the polarizing member 200. The cover window 300 may protect the display panel 100 and may be transparent. The cover window 300 may include a polymer material, a thin glass film, or the like to enable bending.

In an embodiment, for example, the cover window 300 may include ultra-thin glass (“UTG”). The ultra-thin glass may be tempered to have a predetermined stress profile therein. The ultra-thin glass can more effectively prevent crack generation, propagation of cracks, damage, and the like due to external impact than before tempering. The ultra-thin glass may have various stresses for each area through a tempering process.

In an embodiment, for example, the ultra-thin glass of the cover window 300 may be chemically tempered thin glass to have high strength. However, this is an example and embodiments are not limited thereto. In an embodiment, for example, the ultra-thin glass of the cover window 300 may be a thermally tempered thin film glass.

In an embodiment where the glass is composed of an ultra-thin film or a thin film, the glass may have a flexible characteristic and may have a characteristic of being bent, folded, or rolled. In an embodiment, for example, the cover window 300 may include glass such as soda lime glass, alkali alumino silicate glass, borosilicate glass, lithium alumina silicate glass, or the like. These can be used alone or in a combination thereof. However, embodiments are not limited thereto, and the cover window 300 may include various types of glass.

An adhesive member 610 may be disposed between the polarizing member 200 and the cover window 300. The adhesive member 610 may attach the polarizing member 200 and the cover window 300 to each other. In an embodiment, for example, the adhesive member 610 may include an optical clear adhesive (“OCA”), a pressure sensitive adhesive (“PSA”), a photocurable resin, a thermosetting resin, or the like. These can be used alone or in a combination thereof.

The window protection layer 400 may be disposed on the cover window 300. The window protection layer 400 may perform at least one function of preventing scattering, shock absorption, stamping prevention, fingerprint prevention, or glare prevention of the cover window 300. The window protection layer 400 may include a transparent polymer film. In an embodiment, for example, the window protection layer 400 may include epoxy resin, polyurethane, polyester, polyethylene terephthalate, polyethylene naphthalate, polyimide, polyarylate, polycarbonate, polymethyl methacrylate, ethyl vinyl acetate, polyamide resin, or the like. These can be used alone or in a combination thereof.

In an embodiment, an adhesive member 620 may be disposed between the cover window 300 and the window protection layer 400. The adhesive member 620 may attach the cover window 300 and the window protection layer 400 to each other. In another embodiment, the adhesive member 620 between the cover window 300 and the window protection layer 400 may be omitted, and the window protection layer 400 may be disposed directly on an upper surface of the cover window 300. In an embodiment, for example, the window protection layer 400 may be directly bonded to the cover window 300 by thermocompression bonding, but this is an example and embodiments are not limited thereto.

The support member 500 may be disposed under the display panel 100 (e.g., in the direction opposite to the third direction D3). The support member 500 may protect the display panel 100 from an external environment under the display panel 100, and may support the display panel 100. A rigidity of the support member 500 may be greater than a rigidity of the display panel 100. Accordingly, the support member 500 may effectively prevent the display panel 100 from being deformed due to an external force or the like.

In an embodiment, the support member 500 may include a first support layer 510 and a second support layer 520 disposed under the first support layer 510. Each of the first support layer 510 and the second support layer 520 may include the first area NFA1, the second area NFA2, and the third area FA.

The first support layer 510 may include a polymer resin and may have flexibility. The first support layer 510 may be a thermocompression bonding film capable of being bonded to a metal layer, or the like via thermocompression bonding. In an embodiment, for example, the first support layer 510 may include polyethylene terephthalate (PET), but this is an example and embodiments are not limited thereto. In an embodiment, for example, a thickness T1 of the first support layer 510 may be in a range of about 10 micrometers (μm) to about 50 μm.

An adhesive member 630 may be disposed between the display panel 100 and the first support layer 510. The adhesive member 630 may attach the display panel 100 and the first support layer 510 to each other. That is, the adhesive member 630 may attach the display panel 100 and the support member 500 to each other.

The second support layer 520 may be disposed under the first support layer 510. A rigidity of the second support layer 520 may be greater than a rigidity of the first support layer 510. In an embodiment, the second support layer 520 may include a metal or alloy. In an embodiment, for example, the second support layer 520 may include a stainless steel (“SUS”), titanium, aluminum, magnesium, titanium alloy, aluminum alloy, magnesium alloy, or the like. In another embodiment, the second support layer 520 may include a reinforced fiber composite. In an embodiment, for example, the second support layer 520 may include a carbon fiber reinforced plastic (“CFRP”), a glass fiber reinforced plastic (“GFRP”), or the like.

In an embodiment, a thickness T2 of the second support layer 520 may be greater than the thickness T1 of the first support layer 510. In an embodiment, for example, the thickness T2 of the second support layer 520 may be in a range of about 20 μm to about 200 μm. When the thickness T2 of the second support layer 520 is excessively small (e.g., less than about 20 μm), the second support layer 520 may not sufficiently support the display panel 100. When the thickness T2 of the second support layer 520 is excessively large (e.g., greater than about 200 μm), it may be difficult to reduce a weight and a thickness of the display device 10.

The second support layer 520 may be disposed directly under the first support layer 510. As will be described later, the first support layer 510 may be directly bonded to the second support layer 520 by thermocompression bonding. Accordingly, the second support layer 520 may directly contact one surface of the first support layer 510. The first support layer 510 may have a first surface 510a facing the display panel 100 and a second surface 510b opposite to the first surface 510a. The second support layer 520 may have a first surface 520a facing the first support layer 510 and a second surface 520b opposite to the first surface 520a. The second surface 510b of the first support layer 510 may directly contact the first surface 520a of the second support layer 520. The second surface 510b of the first support layer 510 and the first surface 520a of the second support layer 520 may be sufficiently strongly bonded by thermocompression bonding. Since the second support layer 520 is disposed directly under the first support layer 510, it is possible to decrease the thickness of the display device 10.

The second support layer 520 may include a first support portion 521, a second support portion 522, and a stretchable portion 523. The first support portion 521, the second support portion 522, and the stretchable portion 523 may overlap the first area NFA1, the second area NFA2, and the third area FA, respectively. The second support portion 522 may be spaced apart from the first support portion 521 in the second direction D2. The stretchable portion 523 may be positioned between the first support portion 521 and the second support portion 522. The stretchable portion 523 may extend in the first direction D1. At least one opening may be defined in the stretchable portion 523 overlapping the third area FA.

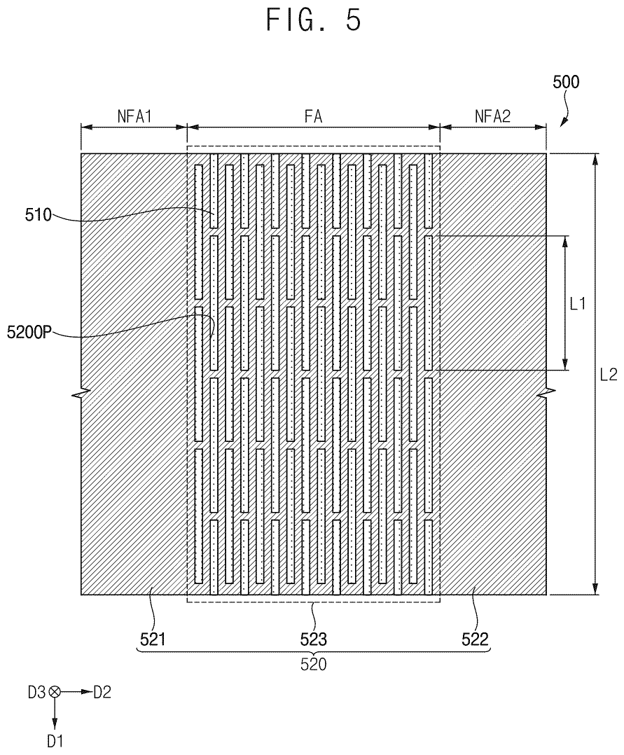

FIG. 5 is a rear view illustrating an example of a support member included in the display device of FIG. 3.

Referring to FIGS. 1, 3, and 5, in an embodiment, a plurality of openings 520OP spaced apart from each other may be defined in the stretchable portion 523 overlapping the third area FA. The plurality of openings 520OP may be formed by removing a portion of the stretchable portion 523 by an etching process after the first support layer 510 and the second support layer 520 are thermocompression bonded.

In an embodiment, each of the plurality of openings 520OP may have a shape extending in the first direction D1. That is, each of the plurality of openings 520OP may extend in a direction parallel to the folding axis FX. Since the plurality of openings 520OP extending in the first direction D1 are defined in the stretchable portion 523, the stretchable portion 523 of the second support layer 520 overlapping the third area FA can be easily bent along the folding axis FX.

The plurality of openings 520OP may be arranged in the first direction D1 and the second direction D2. A length L1 of each of the plurality of openings 520OP in the first direction D1 may be less than a length L2 of the second support layer 520 in the first direction D1. That is, as illustrated in FIG. 5, the plurality of openings 520OP may be arranged to be spaced apart from each other in the first direction D1 in one column. The plurality of openings 520OP arranged in the same column may be arranged parallel to or offset from the plurality of openings 520OP arranged in another adjacent column. In an embodiment of FIG. 5, the first support portion 521, the second support portion 522, and the stretchable portion 523 of the second support layer 520 may be physically connected to each other or integrally formed with each other as a single unitary and indivisible part.

Each of the plurality of openings 520OP may be defined through the stretchable portion 523 in the third direction D3. In an embodiment, for example, as illustrated in FIGS. 3 and 5, each of the plurality of openings 520OP may expose the second surface 510b of the first support layer 510.

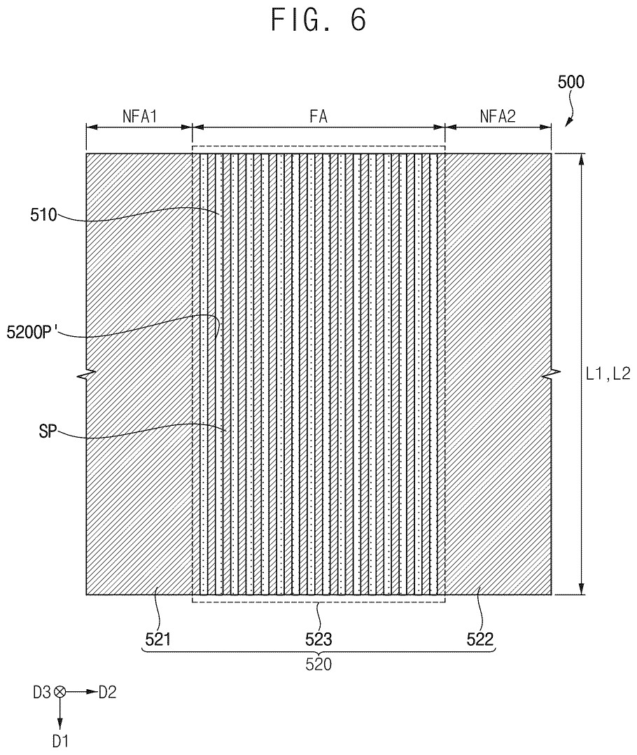

FIG. 6 is a rear view illustrating another example of a support member included in the display device of FIG. 3.

Referring to FIGS. 1, 3, and 6, in an embodiment, a plurality of openings 520OP′ spaced apart from each other may be defined in the stretchable portion 523 overlapping the third area FA. Each of the plurality of openings 520OP′ may have a shape extending in the first direction D1. That is, each of the plurality of openings 520OP′ may extend in the direction parallel to the folding axis FX. Since the plurality of openings 520OP′ extending in the first direction D1 are defined in the stretchable portion 523, the stretchable portion 523 of the second support layer 520 overlapping the third area FA can be easily bent along the folding axis FX.

The plurality of openings 520OP′ may be arranged in the second direction D2. The length L1 of each of the plurality of openings 520OP′ in the first direction D1 may be equal to the length L2 of the second support layer 520 in the first direction D1. That is, each of the plurality of openings 520OP′ may penetrate the stretchable portion 523 in the third direction D3 and in the first direction D1. In other words, the stretchable portions 523 of the second support layer 520 may include a plurality of stripe patterns SP extending in the first direction D1 and spaced apart from each other in the second direction D2. In an embodiment, as shown in FIG. 6, the first support portion 521, the second support portion 522, and the plurality of stripe patterns SP of the stretchable portion 523 of the second support layer 520 may be physically separated or disconnected from each other. As will be described later, since the plurality of openings 520OP′ are formed by removing a portion of the stretchable portion 523 after the second surface 510b of the first support layer 510 and the first surface 520a of the second support layer 520 are sufficiently strongly bonded by thermocompression bonding, the first support portion 521, the second support portion 522, and the plurality of stripe patterns SP of the stretchable portion 523 of the second support layer 520 can be physically separated or disconnected from each other.

Each of the plurality of openings 520OP′ may be defined through the stretchable portion 523 in the third direction D3. In an embodiment, for example, as illustrated in FIGS. 3 and 6, each of the plurality of openings 520OP′ may expose the second surface 510b of the first support layer 510.

In a conventional foldable display device, a first support layer and a second support layer of a support member disposed under a display panel may be attached to each other through an adhesive member. In this case, it may be difficult to reduce a thickness of the support member and a thickness of the foldable display device due to a thickness of the adhesive member. In addition, to enable easily folding of a stretchable portion of the second support layer overlapping the folding area, the adhesive member may be disposed only in non-folding areas excluding a folding area. In this case, since a separation space is formed between the first support layer and the stretchable portion of the second support layer, the support member may not sufficiently support the display panel in the folding area.

In the display device 10 according to embodiments of the invention, the first support layer 510 and the second support layer 520 of the support member 500 may directly contact each other. The first support layer 510 may be directly bonded to the second support layer 520 by thermocompression bonding. Accordingly, since an adhesive member between the first support layer 510 and the second support layer 520 is omitted, it is possible to decrease the thickness of the support member 500 and the thickness of the display device 10. In addition, the first surface 520a of the stretchable portion 523 may contact the second surface 510b of the first support layer 510. Accordingly, the support member 500 may sufficiently support the display panel 100 not only in the first and second areas NFA1 and NFA2 but also in the third area FA.

The display device 10 may further include other components in addition to those described with reference to FIG. 3. In an embodiment, for example, various functional layers such as a digitizer, a shielding layer, a heat dissipation layer, a cushion layer, or the like may be additionally disposed between the display panel 100 and the support member 500 or under the support member 500.

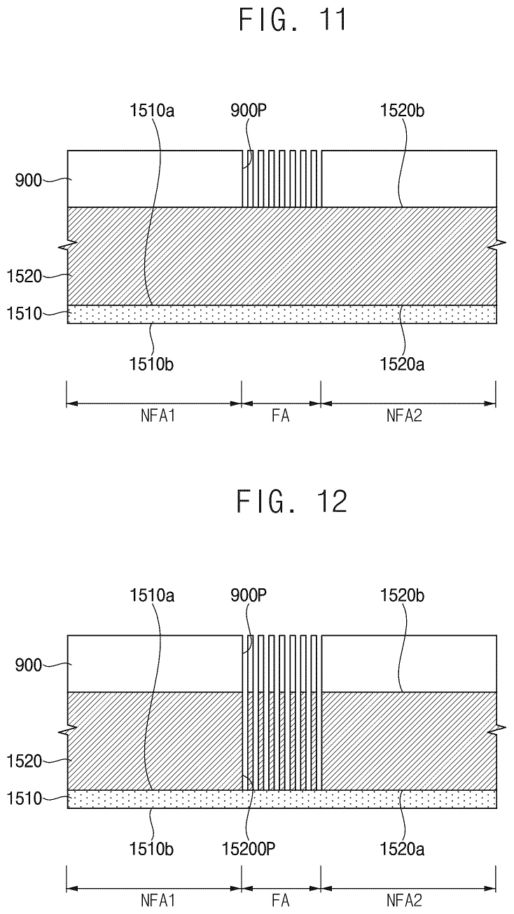

FIGS. 7 to 13 are views schematically illustrating a method of manufacturing a support member for a display device according to an embodiment.

Hereinafter, an embodiment of a method of manufacturing the support member 500 of FIG. 3 will be described with reference to FIGS. 7 to 13. Hereinafter, any repetitive detailed descriptions of the same or like elements as those described above may be omitted or simplified.

Referring to FIG. 7, in an embodiment of a method of manufacturing the support member 500, a second sheet S2 including a different material from a material of a first sheet S1 may be disposed on the first sheet S1. The first sheet S1 may include a polymer resin. The first sheet S1 may be a thermocompression bonding film capable of being bonded to a metal layer, or the like via thermocompression bonding. In an embodiment, for example, the first sheet S1 may include PET. In an embodiment, for example, a thickness of the first sheet S1 may be in a range of about 10 μm to about 50 μm.

The second sheet S2 may include metal, alloy, or reinforced fiber composite. In an embodiment, for example, the second sheet S2 may include SUS, titanium, aluminum, magnesium, titanium alloy, aluminum alloy, magnesium alloy, CFRP, GFRP, or the like. In an embodiment, for example, a thickness of the second sheet S2 may be greater than the thickness of the first sheet S1. In an embodiment, for example, the thickness of the second sheet S2 may be in a range of about 20 μm to about 200 μm.

Each of the first sheet S1 and the second sheet S2 may be provided in the form of a winding roll, and may be supplied in one direction (i.e., in the right direction in FIG. 7) by a pair of supply rollers R1. The pair of supply rollers R1 may each rotate in different directions, so that the first sheet S1 and the second sheet S2 may be supplied between the supply rollers R1. The second sheet S2 may be directly disposed on the first sheet S1 supplied by the supply rollers R1. That is, one surface of the first sheet S1 may directly contact one surface of the second sheet S2.

Thereafter, the first sheet S1 and the second sheet S2 may be thermocompression bonded by thermocompression rollers R2. In an embodiment, for example, the first sheet S1 and the second sheet S2 may be supplied between a pair of thermocompression rollers R2. Each of the thermocompression rollers R2 may include a heater. In an embodiment, for example, a thermocompression temperature in the thermocompression rollers R2 may be in a range of about 220° C. to about 250° C., but this is an example and the embodiments are not limited thereto. The sheet in which the first sheet S1 and the second sheet S2 are (physically) bonded to each other via thermocompression bonding by the thermocompression rollers R2 may be referred to as a third sheet S3.

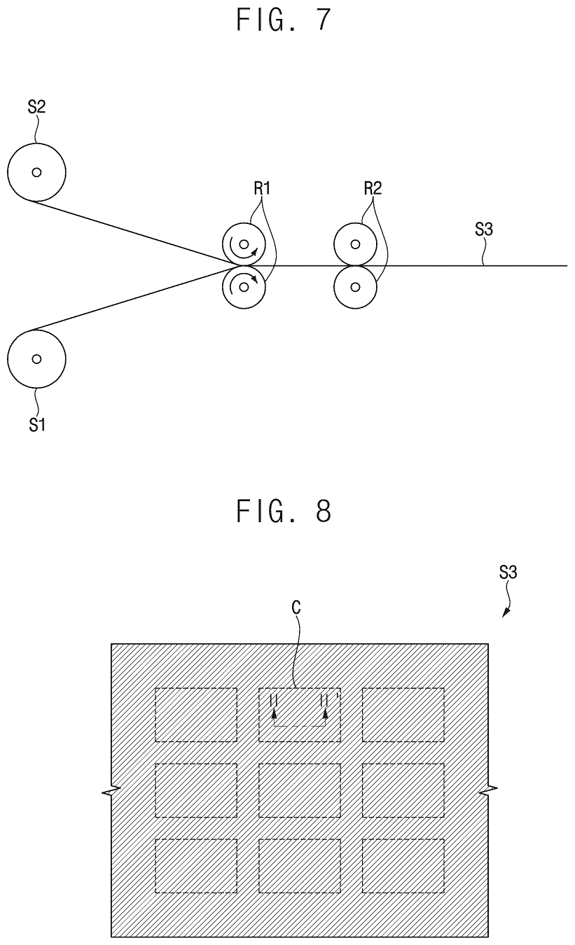

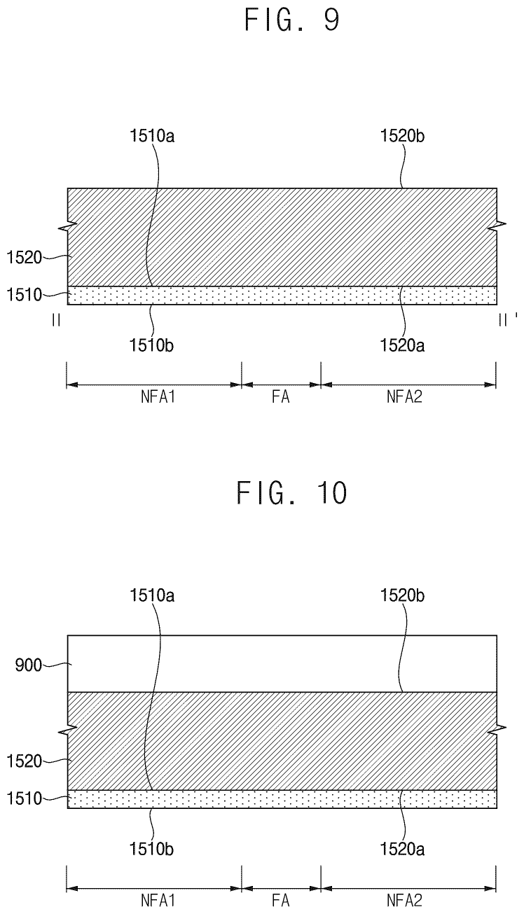

FIG. 8 is a plan view illustrating a portion of the third sheet S3 of FIG. 7. FIG. 9 is a cross-sectional view taken along line II-II′ of FIG. 8.

Referring to FIGS. 8 and 9, the third sheet S3 in which the first sheet S1 and the second sheet S2 are bonded to each other via thermocompression bonding may have a cross-sectional structure in which different material layers contact each other. The third sheet S3 may have a cross-sectional structure in which a second support layer 1520 is directly disposed on a first support layer 1510. The first support layer 1510 may correspond to the first sheet S1, and the second support layer 1520 may correspond to the second sheet S2.

The first support layer 1510 may have a first surface 1510a facing the second support layer 1520 and a second surface 1510b opposite the first surface 1510a. The second support layer 1520 may have a first surface 1520a facing the first support layer 1510 and a second surface 1520b opposite the first surface 1520a. The first surface 1510a of the first support layer 1510 and the first surface 1520a of the second support layer 1520 may directly contact each other.

In an embodiment, as illustrated in FIG. 8, a plurality of cells C may be defined in the third sheet S3 in a plan view. Each of the plurality of cells C may correspond to the support member 500 of FIG. 3. Each of the plurality of cells C may include the first area NFA1, the second area NFA2, and the third area FA positioned between the first area NFA1 and the second area NFA2. As will be described later, after removing a portion of the second support layer 1520 to form a stretchable portion, the plurality of cells C may be punched or cut out from the third sheet S3 to manufacture the support members 500 of FIG. 3.

FIGS. 10 to 13 are cross-sectional views illustrating an etching process of the third sheet S3. Each of FIGS. 10 to 13 may correspond to the cross-sectional view of FIG. 9.

Referring to FIGS. 10 to 13, in an embodiment of an etching process of the third sheet S3, a photoresist layer 900 may be formed on the second support layer 1520 of the third sheet S3. The photoresist layer 900 may be formed on the second surface 1520b of the second support layer 1520. In an embodiment, for example, a dry film photoresist may be attached on the second surface 1520b of the second support layer 1520, but this is an example and embodiments are not limited thereto.

Thereafter, a pattern portion overlapping the third area FA may be formed in the photoresist layer 900. The pattern portion may be formed by exposing and developing the photoresist layer 900 using a photomask (not illustrated). In an embodiment, for example, the pattern portion may be formed to overlap the third area FA of each of the plurality of cells C, and at least one opening may be defined in the pattern portion. Openings having substantially the same planar shape as the openings 520OP of FIG. 5 or the openings 520OP′ of FIG. 6 may be defined in the pattern portion.

Thereafter, the second support layer 1520 may be selectively etched using the photoresist layer 900 including the pattern portion as an etch mask to form a stretchable portion overlapping the third area FA in the second support layer 1520. The second support layer 1520 may be wet etched using an etchant having a high selectivity between the second support layer 1520 and the first support layer 1510. In an embodiment, for example, the etchant may include FeCl₃, but this is an example and embodiments are not limited thereto. As the portion of the second support layer 1520 is selectively removed by the etchant, openings 1520OP overlapping the third area FA may be formed in the second support layer 1520. The openings 1520OP of the second support layer 1520 may have substantially the same planar shape as the openings 520OP of FIG. 5 or the openings 520OP′ of FIG. 6.

The photoresist layer 900 may be removed by an ashing process. After the photoresist layer 900 is removed, the plurality of cells C may be punched or cut out from the third sheet S3 to manufacture the support member 500 of FIG. 3.

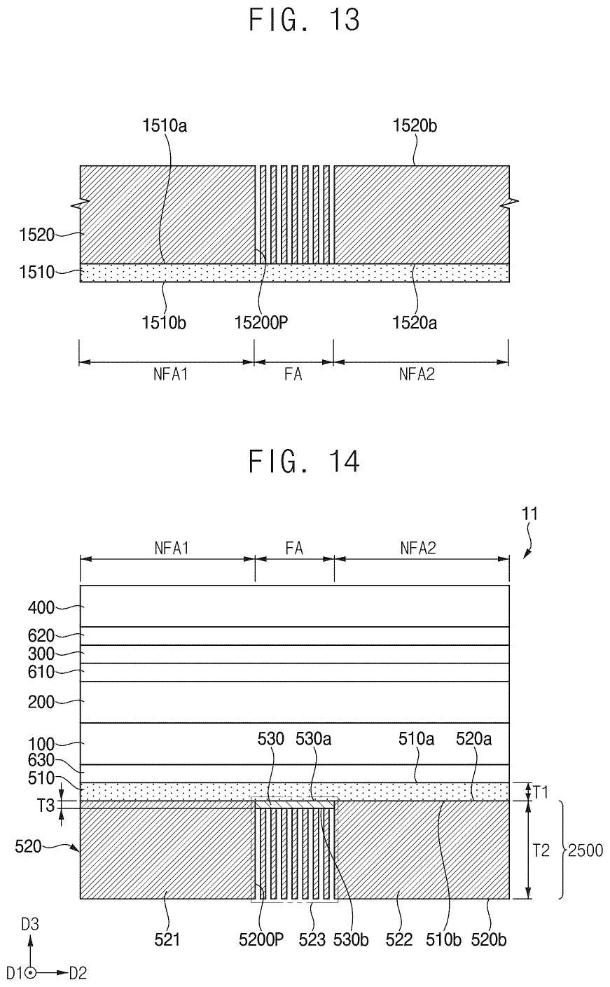

FIG. 14 is a cross-sectional view illustrating a display device according to another embodiment.

A display device 11 of FIG. 14 may be substantially the same as the display device 10 of FIG. 3 except for a support member 2500. Therefore, any repetitive detailed descriptions of the same or like element as those described above with reference to FIG. 3 may be omitted or simplified.

In an embodiment, as shown in FIG. 14, the support member 2500 may include a first support layer 510, a second support layer 520, and a coating layer 530. The first support layer 510 and the second support layer 520 may be substantially the same as the first support layer 510 and the second support layer 520 of FIG. 3. The second support layer 520 may include a first support portion 521, a second support portion 522, and a stretchable portion 523. The stretchable portion 523 may be substantially the same as the stretchable portion 523 illustrated in FIG. 5.

The coating layer 530 may overlap the third area FA and may extend in the first direction D1. The coating layer 530 may be disposed between the first support layer 510 and the stretchable portion 523. In an embodiment, for example, a first surface 530a of the coating layer 530 may directly contact the second surface 510b of the first support layer 510, and a second surface 530b of the coating layer 530 may directly contact the first surface 520a of the stretchable portion 523. The second surface 530b of the coating layer 530 may be a non-adhesive surface. Accordingly, the second surface 530b of the coating layer 530 may be not adhered to the first surface 520a of the stretchable portion 523. In such an embodiment, since the second surface 530b of the coating layer 530 is not adhered to the first surface 520a of the stretchable portion 523, the stretchable portion 523 can be bent more easily. In an embodiment, for example, the coating layer 530 may include a surfactant, fluororesin, or the like.

In such an embodiment, as the coating layer 530 is disposed between the first support layer 510 and the stretchable portion 523, the stretchable portion 523 may be spaced apart from the second surface 510b of the first support layer 510. In such an embodiment, the first support portion 521 and the second support portion 522 may directly contact the second surface 510b of the first support layer 510.

A thickness T3 of the coating layer 530 may be less than each of the thickness T1 of the first support layer 510 and the thickness T2 of the second support layer 520. In an embodiment, for example, the thickness T3 of the coating layer 530 may be in a range of about 0.1 μm to about 10 μm.

In an embodiment, as the coating layer 530 is disposed between the first support layer 510 and the stretchable portion 523, the stretchable portion 523 may protrude slightly downward from the first support portion 521 and the second support portion 522. In an embodiment, for example, other structures may not be disposed directly under the stretchable portion 523. A distance between the second surface 510b of the first support layer 510 and the second surface 520b of the second support layer 520 in the first area NFA1 (or in the second area NFA2) may be less than a distance between the second surface 510b of the first support layer 510 and the second surface 520b of the second support layer 520 in the third area FA. That is, a distance between the second surface 510b of the first support layer 510 and the second surface 520b of the first support portion 521 (or a distance between the second surface 510b of the first support layer 510 and the second surface 520b of the second support portion 522) may be less than a distance between the second surface 510b of the first support layer 510 and the second surface 520b of the stretchable portion 523.

In an embodiment, the coating layer 530 may be formed on the second surface 510b of the first support layer 510 before the first support layer 510 and the second support layer 520 are bonded to each other via thermocompression bonding. In an embodiment, for example, before the first sheet S1 of FIG. 7 passes through the supply rollers R1, the coating layer 530 may be formed on one surface of the first sheet S1. The coating layer 530 may be formed by applying a surfactant or depositing a fluororesin only to a portion of the first sheet S1. After the coating layer 530 is formed on the one surface of the first sheet S1, the second sheet S2 may be disposed on the one surface of the first sheet S1 and the coating layer 530, and the first sheet S1 and the second sheet S2 may be bonded to each other via thermocompression bonding.

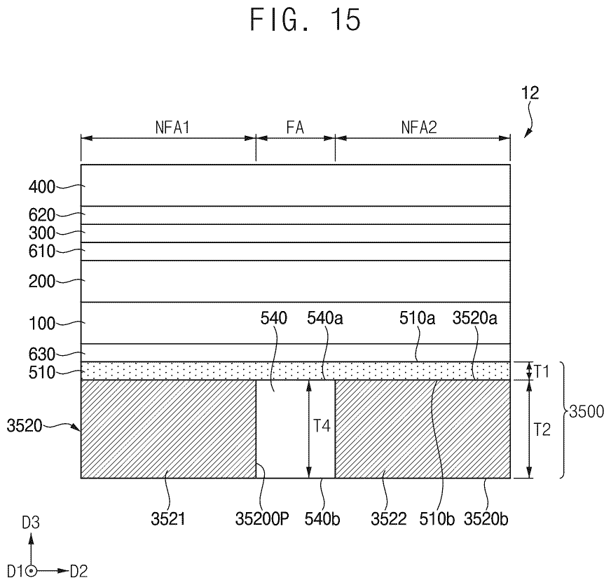

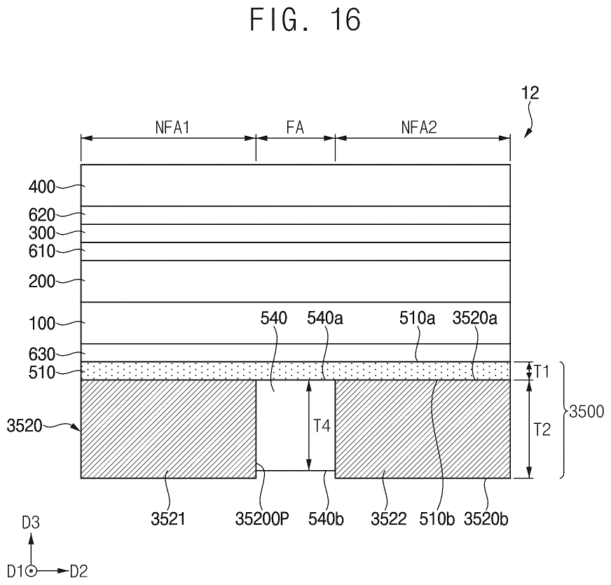

FIGS. 15 and 16 are cross-sectional views illustrating a display device according to still another embodiment.

A display device 12 of FIGS. 15 and 16 may be substantially the same as the display device 10 of FIG. 3 except for a support member 3500. Therefore, any repetitive detailed descriptions of the same or like elements as those described above with reference to FIG. 3 may be omitted or simplified.

In an embodiment, as shown in FIGS. 15 and 16, the support member 3500 may include a first support layer 510, a second support layer 3520, and a first elastic layer 540. The first support layer 510 may be substantially the same as the first support layer 510 of FIG. 3.

The second support layer 3520 may include a first support portion 3521 and a second support portion 3522. The first support portion 3521 may overlap the first area NFA1, and the second support portion 3522 may overlap the second area NFA2. The second support portion 3522 may be spaced apart from the first support portion 3521 in the second direction D2.

An opening 3520OP may be defined between the first support portion 3521 and the second support portion 3522. The opening 3520OP may overlap the entire third area FA and may extend in the first direction D1.

The first elastic layer 540 may be disposed under the first support layer 510 and may be positioned within the opening 3520OP of the second support layer 3520. That is, the first elastic layer 540 may overlap the third area FA and may extend in the first direction D1. The first elastic layer 540 may fill the opening 3520OP of the second support layer 3520.

The first elastic layer 540 may directly contact the second surface 510b of the first support layer 510. The first elastic layer 540 may have a first surface 540a facing the first support layer 510 and a second surface 540b opposite the first surface 540a. The first surface 540a of the first elastic layer 540 may directly contact the second surface 510b of the first support layer 510.

In an embodiment, the first elastic layer 540 may directly contact an inner side surface of the second support layer 3520 defining the opening 3520OP. Both opposing side surfaces of the first elastic layer 540 may directly contact the inner side surface of the second support layer 3520.

In an embodiment, the first elastic layer 540 may include a filler. In an embodiment, for example, after the first support layer 510 and the second support layer 3520 are bonded to each other via thermocompression bonding, a portion of the second support layer 3520 overlapping the entire third area FA may be removed by an etching process to define the opening 3520OP. Thereafter, the first elastic layer 540 may be formed by filling the opening 3520OP of the second support layer 3520 with a filling material and curing the filling material.

In another embodiment, the first elastic layer 540 may be an elastomer sheet. In an embodiment, for example, the elastomer sheet cut to correspond to the opening 3520OP of the second support layer 3520 may be inserted into the opening 3520OP of the second support layer 3520. The elastomer sheet may have adhesive properties. Accordingly, the first elastic layer 540 may be attached to the second surface 510b of the first support layer 510 and the inner side surface of the second support layer 3520.

In an embodiment, as illustrated in FIG. 15, a thickness T4 of the first elastic layer 540 may be substantially the same as a thickness T2 of the second support layer 3520. In another embodiment, as illustrated in FIG. 16, the thickness T4 of the first elastic layer 540 may be less than the thickness T2 of the second support layer 3520. In an embodiment where the first elastic layer 540 is an elastomer sheet, the second surface 540b of the first elastic layer 540 may be an adhesive surface. In such an embodiment, by making the thickness T4 of the first elastic layer 540 less than the thickness T2 of the second support layer 3520, it is possible to prevent the first elastic layer 540 from adhering to a structure that may be placed thereunderneath.

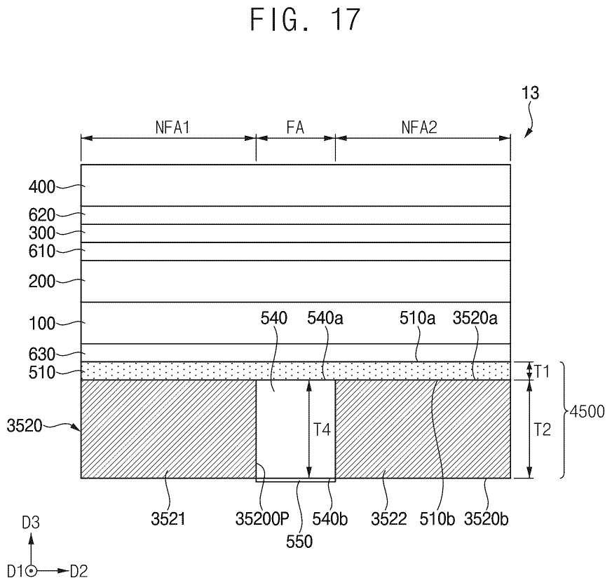

FIG. 17 is a cross-sectional view illustrating a display device according to still another embodiment.

A display device 13 of FIG. 17 may be substantially the same as the display device 12 of FIG. 15 except for a support member 4500. Therefore, any repetitive detailed descriptions of the same or like elements as those described above with reference to FIG. 15 may be omitted or simplified.

In an embodiment, as shown in FIG. 17, the support member 4500 may include a first support layer 510, a second support layer 3520, a first elastic layer 540, and a second elastic layer 550. The first support layer 510, the second support layer 3520, and the first elastic layer 540 may be substantially the same as the first support layer 510, the second support layer 3520, and the first elastic layer 540 of FIG. 15.

The thickness T4 of the first elastic layer 540 may be substantially the same as the thickness T2 of the second support layer 3520. The second surface 540b of the first elastic layer 540 may be an adhesive surface. In an embodiment, for example, the first elastic layer 540 may be an elastomer sheet.

The second elastic layer 550 may be disposed under the first elastic layer 540. The second elastic layer 550 may have a planar shape corresponding to the first elastic layer 540. That is, the second elastic layer 550 may overlap the third area FA and may extend in the first direction D1.

The second elastic layer 550 may be attached on the second surface 540b of the first elastic layer 540. In an embodiment, for example, an adhesive member such as PSA may be disposed between the first elastic layer 540 and the second elastic layer 550. The second elastic layer 550 may have a first surface facing the first elastic layer 540 and a second surface opposite the first surface. The second surface of the second elastic layer 550 may be a non-adhesive surface. Accordingly, the first elastic layer 540 and the second elastic layer 550 may not be adhered to a structure that may be placed underneath.

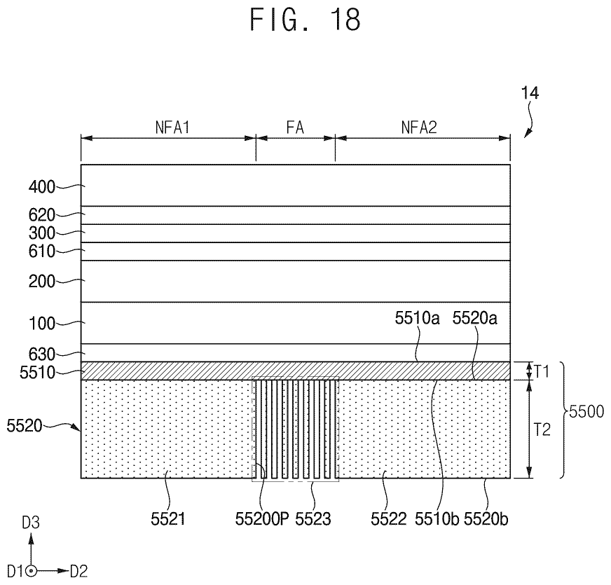

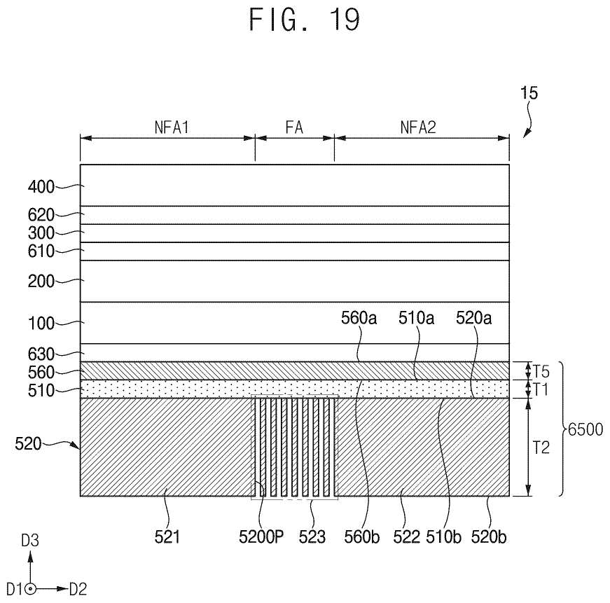

FIG. 18 is a cross-sectional view illustrating a display device according to still another embodiment.

A display device 14 of FIG. 18 may be substantially the same as the display device 10 of FIG. 3 except for a support member 5500. Therefore, any repetitive detailed descriptions of the same or like elements as those described above with reference to FIG. 3 may be omitted or simplified.

In an embodiment, as shown in FIG. 18, the support member 5500 may include a first support layer 5510 and a second support layer 5520. A rigidity of the first support layer 5510 may be greater than a rigidity of the second support layer 5520. The second support layer 5520 may include metal, alloy, or reinforced fiber composite. In an embodiment, for example, the second support layer 5520 may include SUS, titanium, aluminum, magnesium, titanium alloy, aluminum alloy, magnesium alloy, CFRP, GFRP, or the like. The first support layer 5510 may have a sufficiently thin thickness to enable bending.

The second support layer 5520 may be disposed under the first support layer 5510. The second support layer 5520 may include a polymer resin. The second support layer 5520 may be a thermocompression film capable of being bonded to a metal layer, or the like via thermocompression bonding. In an embodiment, for example, the second support layer 5520 may include PET. A thickness T2 of the second support layer 5520 may be greater than a thickness T1 of the first support layer 5510.

The second support layer 5520 may be disposed directly under the first support layer 5510. The second support layer 5520 may be directly bonded to a lower surface of the first support layer 5510 by thermocompression bonding. Accordingly, the second support layer 520 may directly contact one surface of the first support layer 510. The first support layer 5510 may have a first surface 5510a facing the display panel 100 and a second surface 5510b opposite to the first surface 5510a. The second support layer 5520 may have a first surface 5520a facing the first support layer 5510 and a second surface 5520b opposite to the first surface 5520a. The second surface 5510b of the first support layer 510 may directly contact the first surface 5520a of the second support layer 5520. The second surface 5510b of the first support layer 5510 and the first surface 5520a of the second support layer 5520 may be sufficiently strongly bonded to each other by thermocompression bonding. Since the second support layer 5520 is disposed directly under the first support layer 5510, it is possible to decrease the thickness of the display device 14.

The second support layer 5520 may include a first support portion 5521, a second support portion 5522, and a stretchable portion 5523. The first support portion 5521, the second support portion 5522, and the stretchable portion 5523 may overlap the first area NFA1, the second area NFA2, and the third area FA, respectively. The second support portion 5522 may be spaced apart from the first support portion 5521 in the second direction D2. The stretchable portion 5523 may be positioned between the first support portion 5521 and the second support portion 5522. The stretchable portion 5523 may extend in the first direction D1. At least one opening may be defined in the stretchable portion 5523 that overlaps the third area FA.

In an embodiment, for example, a plurality of openings 5520OP having substantially the same planar shape as the openings 520OP of FIG. 5 or the openings 520OP′ of FIG. 6 may be defined in the stretchable portion 5523. The plurality of openings 5520OP may be formed by removing a portion of the stretchable portion 5523 after the first support layer 5510 and the second support layer 5520 are bonded to each other via thermocompression bonding. In an embodiment, for example, the portion of the stretchable portion 5523 may be removed by a laser processing using CO₂ laser, UV laser, picosecond laser, femtosecond laser, or the like.

FIG. 19 is a cross-sectional view illustrating a display device according to still another embodiment.

A display device 15 of FIG. 19 may be substantially the same as the display device 10 of FIG. 3 except for a support member 6500. Therefore, any repetitive detailed descriptions of the same or like elements as those described above with reference to FIG. 3 may be omitted or simplified.

In an embodiment, as shown in FIG. 19, the support member 6500 may include a first support layer 510, a second support layer 520, and a third support layer 560. The first support layer 510 and the second support layer 520 may be substantially the same as the first support layer 510 and the second support layer 520 of FIG. 3.

The third support layer 560 may be disposed on the first support layer 510. The third support layer 560 may be disposed between the display panel 100 and the first support layer 510. An adhesive member 630 may be disposed between the display panel 100 and the third support layer 560. The adhesive member 630 may attach the display panel 100 and the third support layer 560 to each other. That is, the adhesive member 630 may attach the display panel 100 and the support member 6500 to each other.

A rigidity of the third support layer 560 may be greater than a rigidity of the first support layer 510. In an embodiment, the third support layer 560 may include a same material as the second support layer 520. In an embodiment, for example, the third support layer 560 may include SUS, titanium, aluminum, magnesium, titanium alloy, aluminum alloy, magnesium alloy, CFRP, GFRP, or the like. In another embodiment, the third support layer 560 may include a material different from a material of the second support layer 520.

The third support layer 560 may have a sufficiently thin thickness to enable bending. A thickness T5 of the third support layer 560 may be less than the thickness T2 of the second support layer 520.

The third support layer 560 may be disposed directly on the first support layer 510. The third support layer 560 may be bonded onto the first support layer 510 by thermocompression bonding. Accordingly, the third support layer 560 may directly contact one surface of the first support layer 510. The third support layer 560 may have a first surface 560a facing the display panel 100 and a second surface 560b opposite the first surface 560a. The second surface 560b of the third support layer 560 may directly contact the first surface 510a of the first support layer 510. The first support layer 510, the second support layer 520, and the third support layer 560 may be simultaneously bonded to each other via thermocompression bonding.

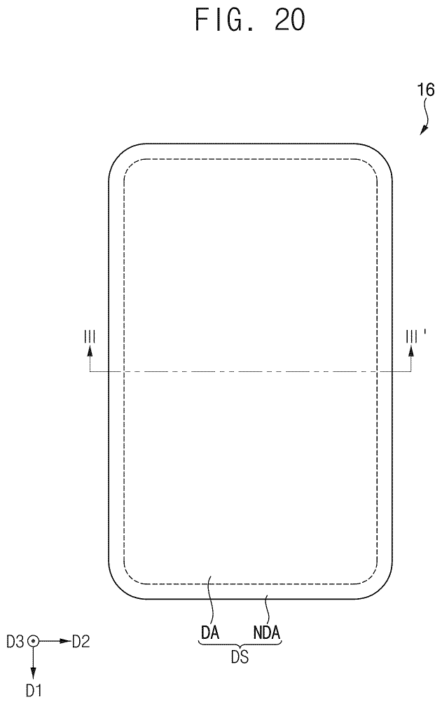

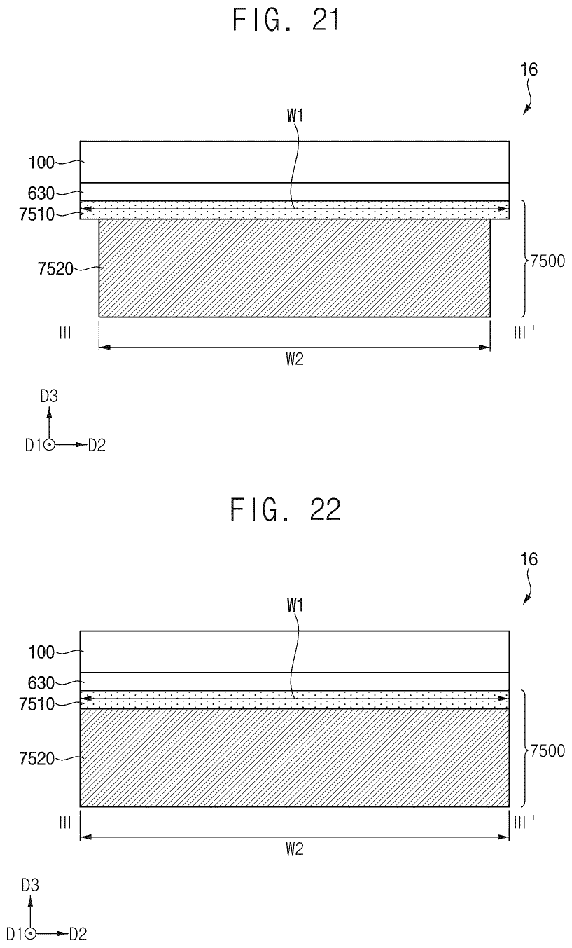

FIG. 20 is a plan view illustrating a display device according to still another embodiment. FIGS. 21 to 23 are cross-sectional views taken along line II-II′ of FIG. 20.

Referring to FIGS. 20 to 23, in an embodiment of a display device 16, an upper surface of a display device 16 may be defined as a display surface DS. The display surface DS may include a display area DA and a non-display area NDA. In FIGS. 20 to 23, for convenience, embodiments of the display device 16 including a display panel 100, an adhesive member 630, and a support member 7500 are illustrated, but the display device 16 may further include various functional layers such as a polarizing member, a cover window, a window protection layer, a digitizer, a shielding layer, a heat dissipation layer, a cushion layer, or the like.

In an embodiment, as shown in FIGS. 20 to 23, the display device 16 may be a non-folding display device. That is, the display device 16 may not include a folding area. The display panel 100 may be a flexible display panel or a rigid display panel.

The support member 7500 may be disposed under the display panel 100. The support member 7500 may protect the display panel 100 from an external environment under the display panel 100, and may support the display panel 100. A rigidity of the support member 7500 may be greater than a rigidity of the display panel 100. Accordingly, the support member 7500 may prevent the display panel 100 from being deformed due to an external force or the like.

The support member 7500 may include a first support layer 7510 and a second support layer 7520 disposed under the first support layer 7510. The first support layer 7510 may include a polymer resin and may have flexibility. The first support layer 7510 may be a thermocompression film capable of being bonded to a metal layer, or the like via thermocompression bonding. In an embodiment, for example, the first support layer 7510 may include PET.

An adhesive member 630 may be disposed between the display panel 100 and the first support layer 7510. The adhesive member 630 may attach the display panel 100 and the first support layer 7510 to each other. That is, the adhesive member 630 may attach the display panel 100 and the support member 7500 to each other.

The second support layer 7520 may be disposed under the first support layer 7510. A rigidity of the second support layer 7520 may be greater than a rigidity of the first support layer 7510. The second support layer 7520 may include metal, alloy, or reinforced fiber composite. For example, the second support layer 7520 may include SUS, titanium, aluminum, magnesium, titanium alloy, aluminum alloy, magnesium alloy, CFRP, GFRP, or the like.

In an embodiment, a thickness of the second support layer 7520 may be greater than a thickness of the first support layer 7510. In an embodiment, for example, the thickness of the first support layer 7510 may be in a range of about 10 μm to about 50 μm. In an embodiment, for example, the thickness of the second support layer 7520 may be in a range of about 20 μm to about 200 μm.

The second support layer 7520 may be disposed directly under the first support layer 7510. The first support layer 7510 may be directly bonded onto the second support layer 7520 by thermocompression bonding. Accordingly, the second support layer 7520 may directly contact one surface of the first support layer 7510.

In an embodiment, as illustrated in FIG. 21, a width W2 of the second support layer 7520 in the second direction D2 may be less than a width W1 of the first support layer 7510 in the second direction D2. In an embodiment, for example, after the first support layer 7510 and the second support layer 7520 are bonded to each other via thermocompression bonding, at least a portion of an edge of the second support layer 7520 may be removed by an etching process. The etching process may be performed using an etchant having a high selectivity between the second support layer 7520 and the first support layer 7510. For example, the etchant may include FeCl₃. The etching process may be performed before the support member 7500 is attached under the display panel 100. In addition, after the support member 7500 is attached under the display panel 100, selectively, at least a portion of an edge of the display panel 100 and at least a portion of an edge of the first support layer 7510 may be removed together by a laser processing using CO₂ laser, UV laser, picosecond laser, femtosecond laser, or the like.

In an embodiment, as illustrated in FIG. 22, the width W2 of the second support layer 7520 in the second direction D2 may be equal to the width W1 of the first support layer 7510 in the second direction D2. In an embodiment, for example, after the first support layer 7510 and the second support layer 7520 are bonded to each other via thermocompression bonding, at least a portion of the edge of the first support layer 7510 and at least a portion of the edge of the second support layer 7520 may be removed together by a laser processing using a water guided laser. The laser processing may be performed before or after the support member 7500 is attached under the display panel 100.

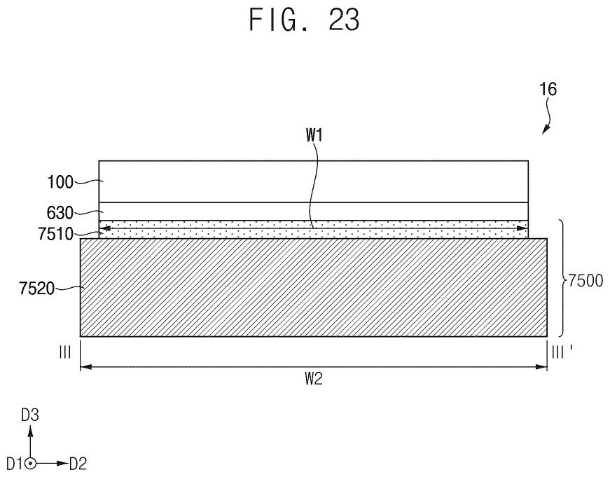

In an embodiment, as illustrated in FIG. 23, the width W2 of the second support layer 7520 in the second direction D2 may be greater than the width W1 of the first support layer 7510 in the second direction D2. In an embodiment, for example, after the first support layer 7510 and the second support layer 7520 are bonded to each other via thermocompression bonding, at least a portion of the edge of the first support layer 7510 may be removed by a laser processing using CO₂ laser, UV laser, picosecond laser, femtosecond laser, or the like. The second support layer 7520 may not be removed by the laser processing. The laser processing may be performed before or after the support member 7500 is attached under the display panel 100.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A support member for a display device comprising:
a first support layer including a first area, a second area, and a third area between the first area and the second area; and
a second support layer directly contacting a first surface of the first support layer, wherein the second support layer includes a material different from a material of the first support layer,
wherein the second support layer includes a stretchable portion, and
wherein the stretchable portion overlaps the third area, and at least one opening is defined in the stretchable portion.

2. The support member for the display device of claim 1, wherein a thickness of the second support layer is greater than a thickness of the first support layer.

3. The support member for the display device of claim 2, wherein
the first support layer includes a polymer resin, and
the second support layer includes at least one selected from a metal, an alloy, and a reinforced fiber composite.

4. The support member for the display device of claim 2, wherein
the first support layer includes at least one selected from a metal, an alloy, and a reinforced fiber composite, and
the second support layer includes a polymer resin.

5. The support member for the display device of claim 1, wherein
the third area extends in a first direction, and
a plurality of openings spaced apart from each other are defined in the stretchable portion of the second support layer, wherein each of the plurality of openings extends in the first direction.

6. The support member for the display device of claim 5, wherein
a length of each of the plurality of openings in the first direction is less than a length of the second support layer in the first direction, and
the plurality of openings are arranged in the first direction and a second direction crossing the first direction.

7. The support member for the display device of claim 6, further comprising:
a coating layer overlapping the third area, extending in the first direction, and disposed between the first support layer and the second support layer.

8. The support member for the display device of claim 7, wherein
a first surface of the coating layer directly contacts the first surface of the first support layer, and
a second surface of the coating layer opposite to the first surface is not adhered to the stretchable portion of the second support layer.

9. The support member for the display device of claim 7, wherein
the second support layer further includes a first support portion overlapping the first area and a second support portion overlapping the second area,
the first support portion and the second support portion are directly contact the first surface of the first support layer, and
the stretchable portion is spaced apart from the first surface of the first support layer.

10. The support member for the display device of claim 7, wherein
the second support layer includes a first surface facing the first surface of the first support layer and a second surface opposite to the first surface, and
a distance between the first surface of the first support layer and the second surface of the second support layer in the first area is less than a distance between the first surface of the first support layer and the second surface of the second support layer in the third area.

11. The support member for the display device of claim 5, wherein
a length of each of the plurality of openings in the first direction is equal to a length of the second support layer in the first direction, and
the plurality of openings are arranged in a second direction crossing the first direction.

12. The support member for the display device of claim 1, wherein
the third area extends in a first direction, and
an opening extending in the first direction and overlapping the entire third area is defined in the stretchable portion of the second support layer.

13. The support member for the display device of claim 12, further comprising:
a first elastic layer overlapping the third area, extending in the first direction, positioned within the opening of the second support layer, and directly contacting the first surface of the first support layer.

14. The support member for the display device of claim 13, wherein the first elastic layer directly contacts an inner side surface of the second support layer, wherein the inner side surface defines the opening.

15. The support member for the display device of claim 13, wherein a thickness of the first elastic layer is equal to a thickness of the second support layer.

16. The support member for the display device of claim 15, wherein
the first elastic layer has a first surface facing the first surface of the first support layer and a second surface opposite to the first surface, and
the support member for the display device further comprises a second elastic layer attached on the second surface of the first elastic layer.

17. The support member for the display device of claim 13, wherein a thickness of the first elastic layer is less than a thickness of the second support layer.

18. The support member for the display device of claim 1, further comprising:
a third support layer directly contacting a second surface of the first support layer and including a same material as the first support layer, and
wherein the second surface of the first support layer is opposite to the first surface of the support layer.

19. A display device comprising:
a display panel including a first non-folding area, a second non-folding area, and a folding area between the first non-folding area and the second non-folding area; and
a support member disposed under the display panel and including:
a first support layer having a first surface facing the display panel and a second surface opposite to the first surface; and
a second support layer directly contacting the second surface of the first support layer, wherein the second support layer includes a material different from a material of the first support layer,
wherein the second support layer includes a stretchable portion, and
wherein the stretchable portion overlaps the folding area, and at least one opening is defined in the stretchable portion.

20. A method of manufacturing a support member for a display device, the method comprising:
directly disposing a second support layer including a material different from a material of a first support layer on the first support layer, the first support layer including a first area, a second area, and a third area between the first area and the second area;
bonding the first support layer and the second support layer to each other via thermocompression bonding;
forming a photoresist layer on the second support layer, wherein the photoresist layer overlaps the third area and includes a pattern portion, in which at least one opening is defined;
forming a stretchable portion in the second support layer by selectively etching the second support layer using the photoresist layer as an etching mask, wherein the stretchable portion overlaps the third area and at least one opening is formed in the stretchable portion; and
removing the photoresist layer.
